(19) United States
(12) Patent Application Publication
(10) Pub. No.: US 2025/0203826 A1
(43) Pub. Date: Jun. 19, 2025

(54) POWER MODULE WITH PLANAR TRANSFORMER

(71) Applicant: Monolithic Power Systems, Inc., Kirkland, WA (US)

(72) Inventors: Kuan-Hung Wu, New Taipei City (TW); Ting-Hung Wang, Taipei City (TW); Chia-Hsi Chang, New Taipei City (TW); Junjie Feng, San Jose, CA (US); Daocheng Huang, San Jose, CA (US)

(21) Appl. No.: 18/980,939

(22) Filed: Dec. 13, 2024

Related U.S. Application Data
(60) Provisional application No. 63/610,617, filed on Dec. 15, 2023.

(51) Int. Cl. H05K 7/20; H01F 27/24; H01F 27/30; H02M 3/00; H05K 1/18

(52) U.S. Cl. CPC H05K 7/209; H01F 27/24; H01F 27/306; H02M 3/003; H02M 3/01; H05K 1/181

(57) ABSTRACT

A power module includes a PCB, a transformer module, and a power converter circuit. The PCB has a top surface and a bottom surface. The transformer module includes a magnetic core, and a primary winding and a secondary winding wound around the magnetic core. The magnetic core has a first core unit arranged on the top surface of the PCB and a second core unit arranged on the bottom surface of the PCB. The primary winding is formed by traces on multiple layers of the PCB, the secondary winding is formed by traces on multiple layers of the PCB, the multiple layers are stacked vertically to form a winding stack. The power converter circuit has power switches, wherein a part of the power switches are disposed on the top surface of the PCB, and another part of the power switches are disposed on the bottom surface of the PCB.

### CROSS-REFERENCE TO RELATED APPLICATION(S)

The present application claims the benefit of and priority to a U.S. Provisional Patent Application Ser. 63/610,617 filed Dec. 15, 2023, which is hereby incorporated fully by reference into the present application.

### TECHNICAL FIELD

The present disclosure relates generally to electronic circuits, and more particularly but not exclusively to power modules.

### BACKGROUND OF THE INVENTION

Power modules are employed to provide one or more voltages to various electronic devices. A power module may integrate a magnetic component, a plurality of power integrated circuits (ICs), a plurality of driver ICs, a plurality of passive devices, etc. Furthermore, to improve integration, the size of the power module needs to be small. In high power applications, large currents also bring challenges to thermal performance of the power module. Therefore, it is desirable to provide a cost-effective power module with high-power density, high-efficiency, excellent heat dissipation capability in space-constrained environments.

### SUMMARY OF THE INVENTION

According to an embodiment of the present disclosure, a power module is provided. The power module includes a printed circuit board (PCB), a transformer module disposed on the printed circuit board, and a power converter circuit. The PCB has a top surface and a bottom surface. The transformer module includes a magnetic core, and a primary winding and a secondary winding wound around the magnetic core. The magnetic core has a first core unit arranged on the top surface of the PCB and a second core unit arranged on the bottom surface of the PCB. The primary winding is formed by traces on multiple layers of the PCB, the secondary winding is formed by traces on multiple layers of the PCB, the multiple layers are stacked vertically to form a winding stack. The power converter circuit has power switches, wherein a part of the power switches are disposed on the top surface of the PCB, and another part of the power switches are disposed on the bottom surface of the PCB.

According to another embodiment of the present disclosure, a planar transformer module is provided. The planar transformer module includes a PCB, a magnetic core, a winding stack and a power converter circuit. The PCB has a top surface and a bottom surface. The magnetic core has at least one leg part passing through multilayers of the PCB, a first unit arranged on the top surface of the PCB and a second unit arranged on the bottom surface of the PCB. The winding stack is formed by traces on the multiple layers of the PCB. The winding stack includes a set of primary layers and a set of secondary layers, and the traces wound around the at least one leg part of the magnetic core. The power converter circuit includes a primary side circuit and a secondary side circuit. The secondary side circuit includes rectifiers. The magnetic core is arranged between two rectifiers on the top surface of the PCB, and the rectifiers are distributed evenly on the top surface and the bottom surface of the PCB.

### BRIEF DESCRIPTION OF THE DRAWINGS

The present disclosure can be further understood with reference to following detailed description and appended drawings, wherein like elements are provided with like reference numerals. These drawings are only for illustration purpose, thus may only show part of the devices and are not necessarily drawn to scale.

FIGS. 1A-1C are schematic diagrams of a power converter circuit in accordance with some embodiments of the present disclosure.

FIG. 2A is a schematic diagram of the power module in accordance with an embodiment of the present disclosure.

FIG. 2B schematically shows a top view of the power module in accordance with an embodiment of the present disclosure.

FIG. 2C schematically shows a bottom view of the power module in accordance with an embodiment of the present disclosure.

FIG. 2D is a side view of the power module in accordance with an embodiment of the present disclosure.

FIG. 3A is a schematic diagram of a magnetic core in accordance with an embodiment of the present disclosure.

FIG. 3B is a schematic diagram of a planar transformer module in accordance with an embodiment of the present disclosure.

FIG. 3C is a schematic diagram of a planar transformer module in accordance with another embodiment of the present disclosure.

FIG. 4A is a bottom view of the first core unit as shown in FIG. 3A in accordance with an embodiment of the present disclosure.

FIG. 4B is a side view of the first core unit as shown in FIG. 3A in accordance with an embodiment of the present disclosure.

FIG. 5A is a schematic diagram of a first core unit in accordance with an alternative embodiment of the present disclosure.

FIG. 5B is a side view of the first core unit in accordance with an alternative embodiment of the present disclosure.

FIG. 6 schematically shows a primary winding formed on one layer of a PCB in accordance with an embodiment of the present disclosure.

FIG. 7 schematically shows a primary winding formed on one layer of a PCB in accordance with another embodiment of the present disclosure.

FIG. 8A shows a schematic diagram of a winding stack in accordance with one embodiment of the present disclosure.

FIG. 8B shows a schematic diagram of a winding stack in accordance with another embodiment of the present disclosure.

### DETAILED DESCRIPTION

Various embodiments of the present disclosure will now be described. In the following description, some specific details, such as example circuits and example values for these circuit components, are included to provide a thorough understanding of embodiments. One skilled in the relevant art will recognize, however, that the present disclosure can be practiced without one or more specific details, or with other methods, components, materials, etc. In other instances, well-known structures, materials, processes or operations are not shown or described in detail to avoid obscuring aspects of the present disclosure.

Throughout the specification and claims, the phrases “in one embodiment”, “in some embodiments”, “in one implementation”, and “in some implementations” as used includes both combinations and sub-combinations of various features described herein as well as variations and modifications thereof. These phrases used herein does not necessarily refer to the same embodiment, although it may. Those skilled in the art should understand that the meanings of the terms identified above do not necessarily limit the terms, but merely provide illustrative examples for the terms. It is noted that when an element is “connected to” or “coupled to” the other element, it means that the element is directly connected to or coupled to the other element, or indirectly connected to or coupled to the other element via another element. Particular features, structures or characteristics may be included in an integrated circuit, an electronic circuit, a combinational logic circuit, or other suitable components that provide the described functionality. In addition, it is appreciated that the figures provided herewith are for explanation purposes to persons ordinarily skilled in the art and that the drawings are not necessarily drawn to scale.

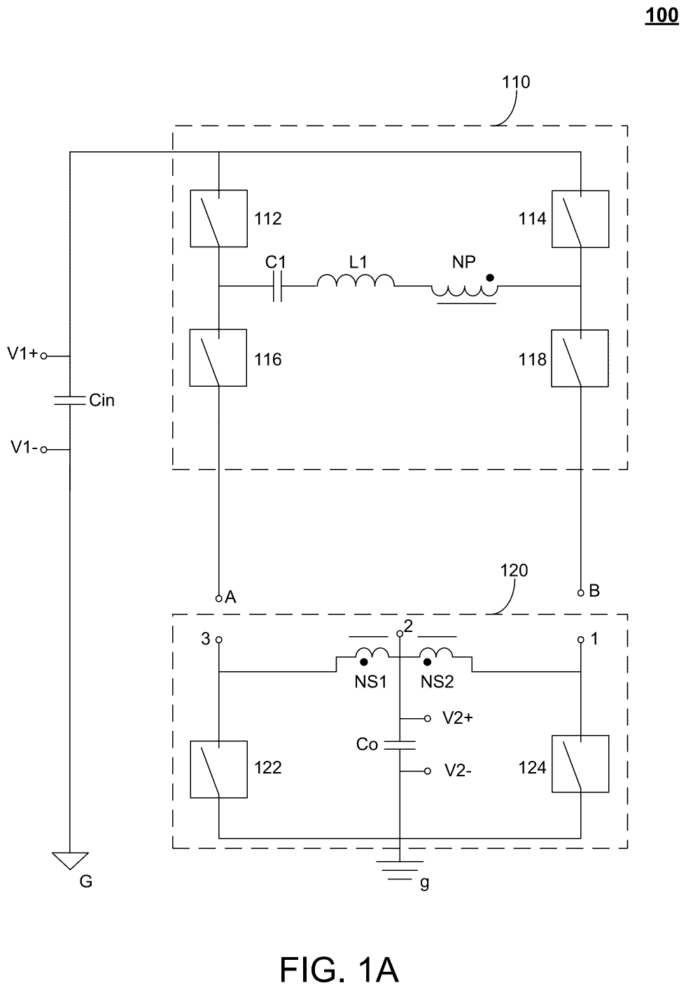

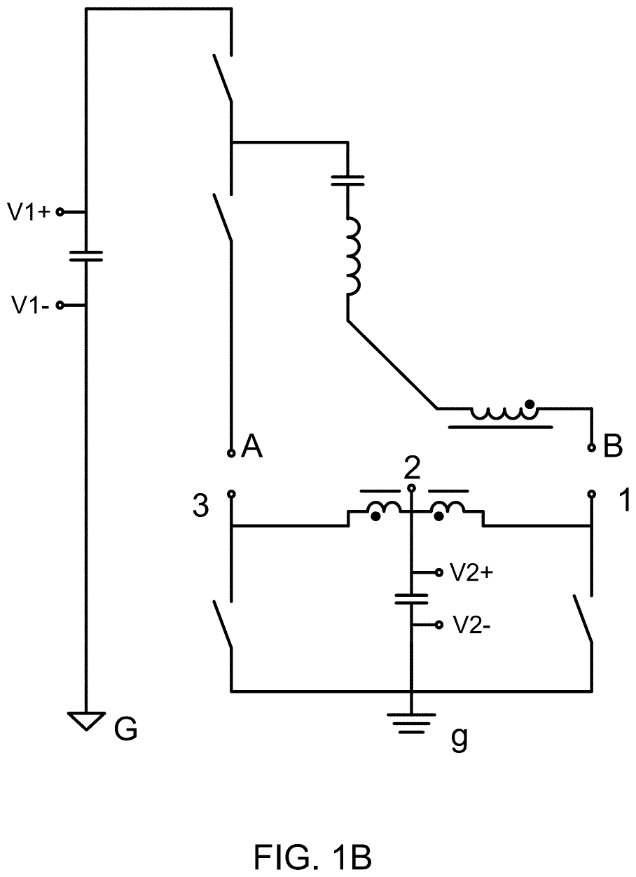

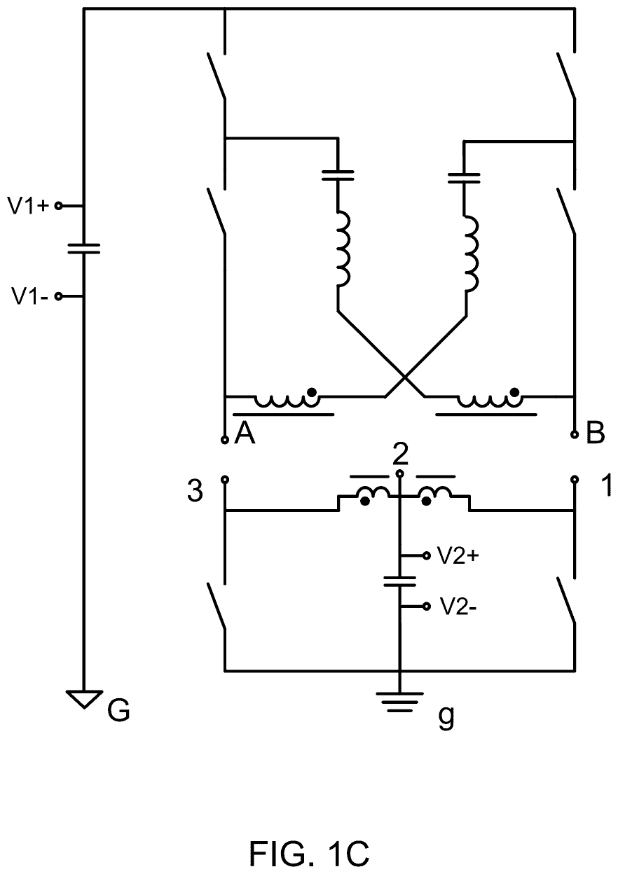

FIG. 1A is a schematic diagram of a power converter circuit 100 in accordance with an embodiment of the present disclosure. The power converter circuit 100 includes a primary side circuit 110 and a secondary side circuit 120 and is configured to convert an input voltage V1 to an output voltage V2. The primary side circuit 110 includes switching units 112, 114, 116, and 118, a capacitor C1, an inductor L1, and a winding NP. The secondary side circuit 120 includes rectifiers 122 and 124, a capacitor Co, and windings NS1 and NS2. In this embodiment, the secondary side circuit 120 includes a center-tapped rectifier circuit. The windings NP, NS1, NS2 and a magnetic core together form a transformer. In some embodiments, the winding NP is referred to as the primary winding, and windings NS1 and NS2 are referred to as the secondary winding. In one implementation, the rectifier 122/124 is a switching unit. In another implementation, the rectifiers 122/124 is a diode.

In the embodiment of FIG. 1A, the primary side circuit 110 includes a full-bridge circuit. In alternative embodiments, the primary side circuit 110 may include a half-bridge circuit as shown in FIG. 1B, a two-phase circuit as shown in FIG. 1C, or other similar circuits and have a configuration different from the one as shown in FIG. 1A.

In one embodiment, each of the switching units 112, 114, 116, 118, 122, and 124 may include a power switch, for example, a metal-oxide-semiconductor field-effect transistor (MOSFET). In some embodiments, one or more of the switching units 112, 114, 116, 118, 122, and 124 may further include a driver circuit (not shown in FIG. 1), and the driver circuit and the corresponding switch are co-packaged into a single integrated circuit (IC).

In the embodiment of FIG. 1A, terminals G and g are configured to receive a ground voltage. In various embodiments, terminals A and B may be coupled to or receive different voltages. In one embodiment, the terminals A and B are coupled to the ground voltage, and the power converter circuit 100 is an isolated LLC resonant converter. In one embodiment, the conversion ratio of the power converter circuit could be expressed as V1/V2 is determined by the transformer turn ratio (i.e., the number of turns N1 of the primary winding NP and the number of turns N2 of the secondary winding NS1/NS2). For instance, for a full-bridge LLC converter, with the transformer turn ratio N1:N2=8:1, when the input voltage is 48V, the output voltage is 6V.

In alternative embodiments, the power converter circuit 100 is a non-isolated LLC resonant converter, and the terminals A and B are not coupled to the ground voltage. For example, the terminal A is coupled to the terminal 3, and the terminal B is coupled to the terminal 1. In this embodiment, suppose the conversion ratio of the power converter circuit V1/V2 is 8:1, the transformer turn ratio N1:N2=6:1.

In another example, the terminals A and B are both coupled to the terminal 2. In this embodiment, suppose the conversion ratio of the power converter circuit V1/V2 is 8:1, the transformer turn ratio N1:N2=7:1.

In yet another example, the terminal A is coupled to the terminal 1, and the terminal B is coupled to the terminal 3. In this embodiment, suppose the conversion ratio of the power converter circuit V1/V2 is 8:1, the transformer turn ratio N1:N2=8:1.

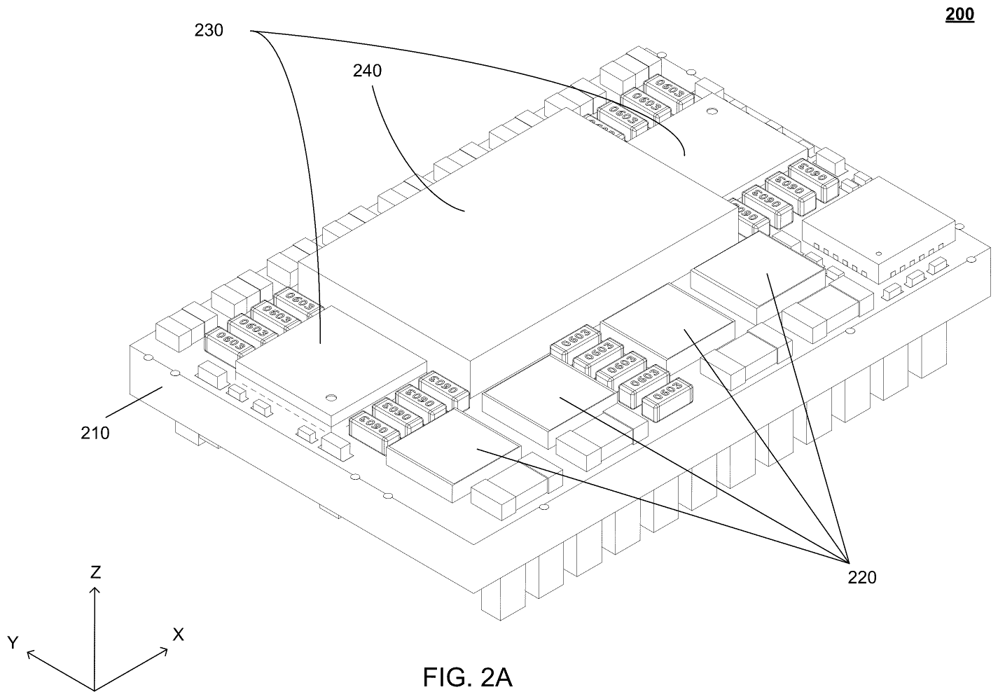

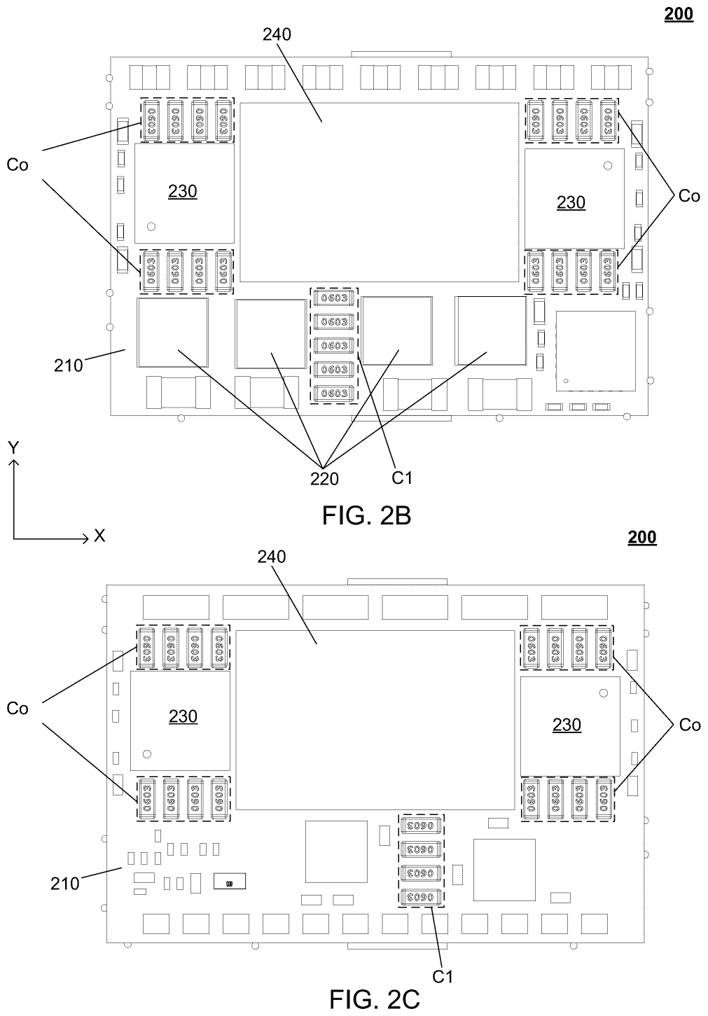

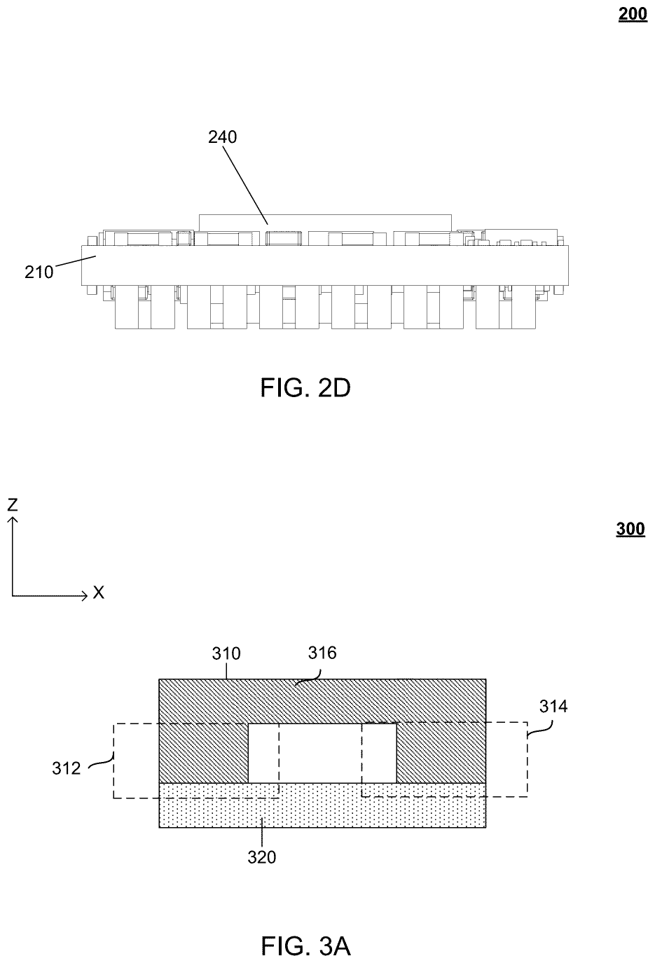

In some embodiments, the power converter circuit 100 is implemented as a power module 200. FIG. 2A is a schematic diagram of the power module 200 in accordance with an embodiment of the present disclosure. FIG. 2B schematically shows a top view of the power module 200 (e.g., a top surface of the PCB 210) in accordance with an embodiment of the present disclosure. FIG. 2C schematically shows a bottom view of the power module 200 (e.g., a bottom surface of the PCB 210) in accordance with an embodiment of the present disclosure. FIG. 2D is a side view of the power module 200 in accordance with an embodiment of the present disclosure.

As shown in FIGS. 2A-2D, the power module 200 includes a printed circuit board (PCB) 210, primary side switches 220, secondary side switches 230, a transformer module 240, and other electronic components, e.g., capacitors. In some embodiments, the primary side switches 220 correspond to the switches of the switching units 112, 114, 116, 118 in the embodiment of FIG. 1A, the secondary side switches 230 correspond to the switches of the switching units 122 and 124 in the embodiment of FIG. 1A, and the transformer module 240 corresponds to the transformer (including the windings NP, NS1, NS2 and the magnetic core) in the embodiment of FIG. 1A.

In one embodiment, the primary side switches 220 disposed on the top surface of the PCB 210 as shown in FIG. 2B. In one embodiment, rectifiers 230 disposed on the top surface of the PCB 210 as shown in FIG. 2B and the bottom surface of the PCB 210 as shown in FIG. 2C. In one implementation, the rectifiers 230 are distributed evenly on the top surface and the bottom surface of the PCB 210. For example, there are 2 rectifiers 230 disposed on the top surface of the PCB 210 as shown in FIG. 2B, and there are 2 rectifiers 230 disposed on the bottom surface of the PCB 210 as shown in FIG. 2C.

In one embodiment, the transformer module 240 is arranged between two rectifiers 230 on the top surface of the PCB 210 as shown in FIG. 2B. In one embodiment, the transformer module 240 is arranged between two rectifiers 230 on the bottom surface of the PCB 210 as shown in FIG. 2C. In some embodiment, the output capacitors Co are arranged adjacent to the rectifiers 230. In one implementation, the rectifier 230 is arranged between the output capacitors Co.

In some embodiments, as shown in FIGS. 2A-2D, the transformer module 240 is arranged between the two secondary side switches 230 in the X direction. Output capacitors (e.g., the capacitor Co as shown in FIG. 1A) are arranged adjacent to the secondary side switches 230 in the Y direction.

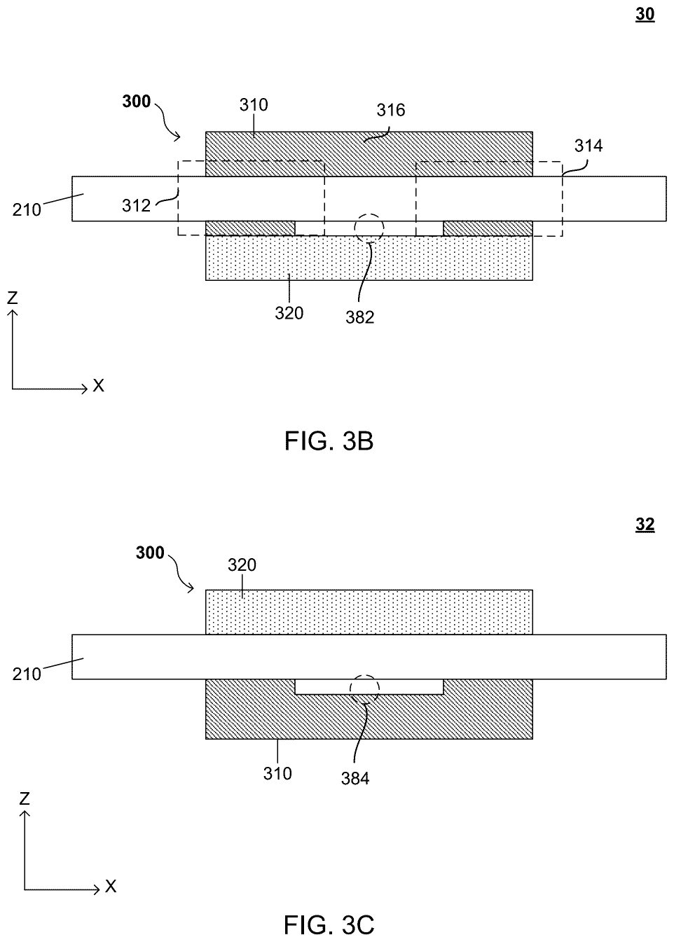

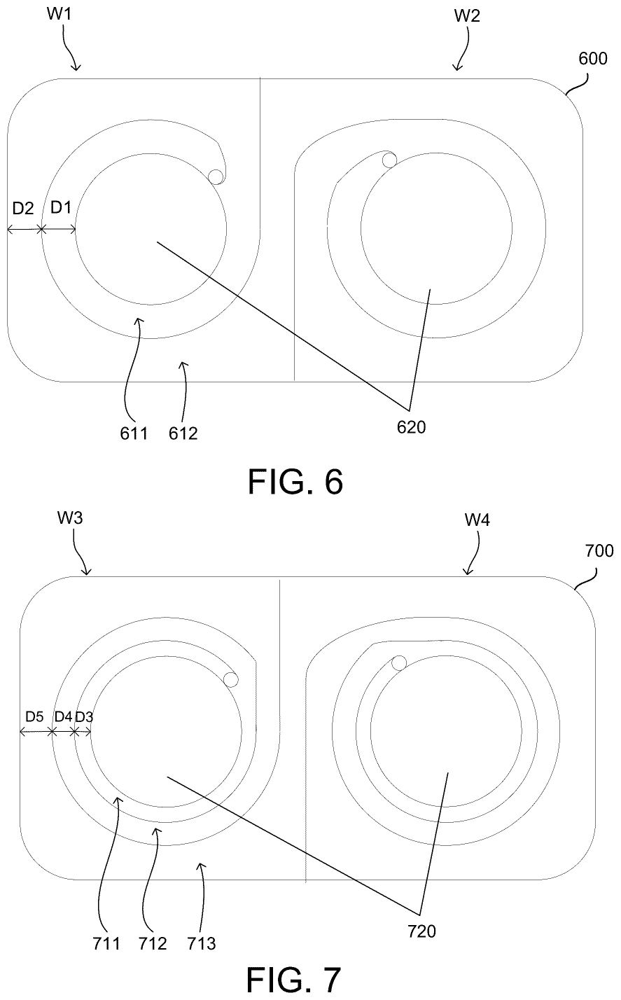

In some embodiments, the transformer module 240 includes a planar transformer. The planar transformer has a magnetic core and windings (e.g., the windings NP, NS1, NS2) that are wound on leg parts of the magnetic core. The windings are formed on printed circuit boards (PCBs) in a spiral form (such as windings W1-W4 as shown in FIGS. 6-7). FIG. 3A is a schematic diagram of a magnetic core 300 in accordance with an embodiment of the present disclosure. In some embodiments, the transformer module 240 in FIGS. 2A-2D includes the magnetic core 300. As shown in FIG. 3A, the magnetic core 300 includes a first core unit 310 and a second core unit 320, and the first core unit 310 includes two leg parts. In some embodiments, the first core unit 310 is referred to as a U-shaped core. Specifically, the U-shaped core has two leg parts 312 and 314 and a connection part 316 connected to the two leg parts 312 and 314. In some embodiments, the second core unit 320 is referred to as an I-shaped core.

FIG. 3B is a schematic diagram of a planar transformer module 30 in accordance with an embodiment of the present disclosure. The magnetic core 300 a magnetic core has at least one leg part (e.g., 312, 314) passing through multilayers of the PCB, a first unit 316 arranged on the top surface of the PCB and a second core unit 320 arranged on the bottom surface of the PCB. As shown in FIG. 3B, the two leg parts of the first core unit 310 extend through the PCB 210, and the first core unit 310 is arranged on the second core unit 320.

FIG. 3C is a schematic diagram of a planar transformer module 32 in accordance with another embodiment of the present disclosure. In the embodiment of FIG. 3C, the second core unit 320 is an I-shaped core, and the first core unit 310 is a U-shaped core. For instance, the second core unit 320 is arranged on the first core unit 310. Specifically, the I-shaped core (e.g., 320) is arranged on the top surface of the PCB, and the U-shaped core is arranged on the bottom surface of the PCB. In some embodiments, the PCB 210 has two holes, so that the two leg parts of the first core unit 310 can extend through the PCB 210.

In the embodiments of FIG. 3B, the first core unit 310 is attached to the PCB 210, and there is a gap 382 between the PCB 210 and the second core unit 320. Similarly, as show in FIG. 3C, the first core unit 310 is attached to the PCB 210, and there is a gap 384 between the PCB 210 and the first core unit 310. Compared with the embodiment of FIG. 3C, since the first unit 316 in the embodiment of FIG. 3B is attached on the top surface of the PCB 210, and there is no gap on the top surface of the PCB 210, the planar transformer module 32 is able to withstand a higher pressure from a heat sink that is to be placed on top of the magnetic core 300 on the top surface of the PCB 210.

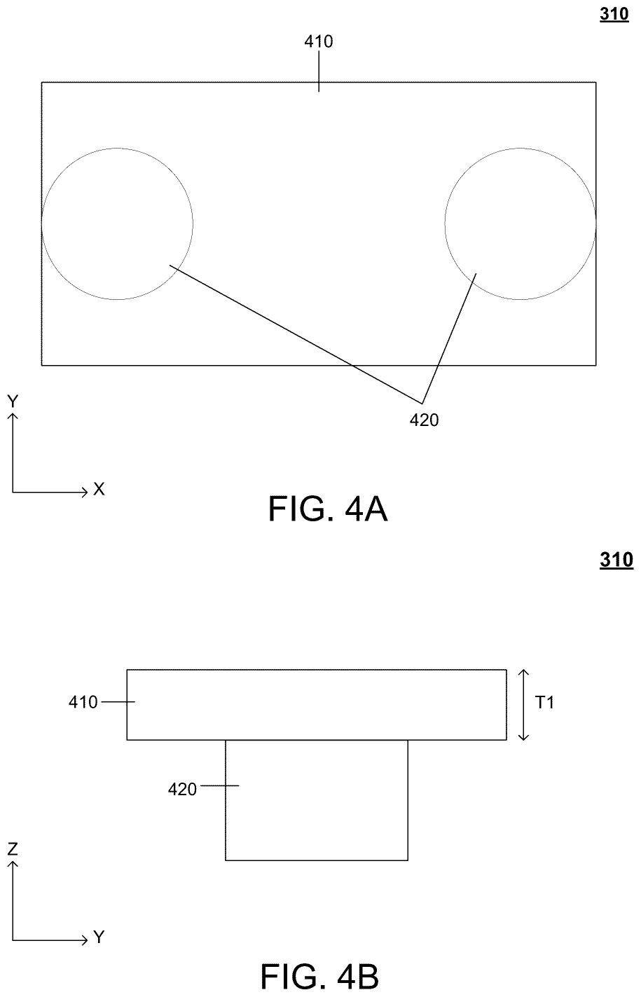

FIG. 4A is a bottom view of the first core unit 310 as shown in FIG. 3A in accordance with an embodiment of the present disclosure. FIG. 4B is a side view of the first core unit 310 as shown in FIG. 3A in accordance with an embodiment of the present disclosure. As shown in FIGS. 4A-4B, the first core unit 310 has two leg parts 420 and a connection part 410 that is connected to the two leg parts 420. The connection part 410 has a thickness T1.

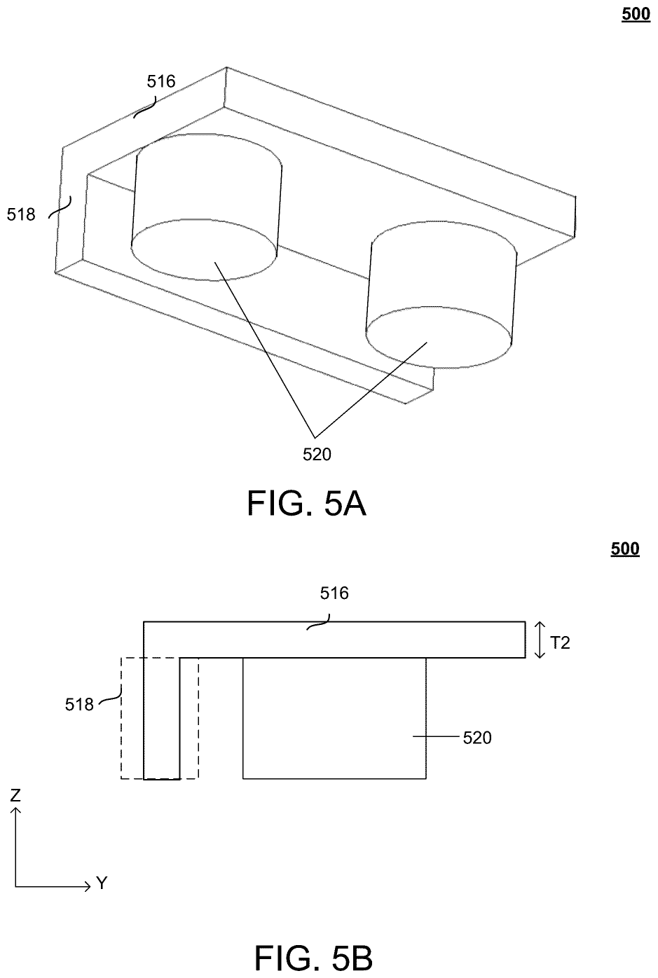

FIG. 5A is a schematic diagram of a first core unit 500 in accordance with an alternative embodiment of the present disclosure. FIG. 5B is a side view of the first core unit 500 in accordance with an alternative embodiment of the present disclosure. In some embodiments, the first core unit 310 as shown in FIG. 3A is replaced with the first core unit 500. In other words, the first core unit 500 and the second core unit 320 together form the magnetic core of the transformer module.

As shown in FIGS. 5A-5B, the first core unit 500 has two leg parts 520 and a connection part 516 that is connected to the two leg parts 520. Compared with the connection part 410 of the first core unit 310 as shown in FIGS. 4A-4B, the first core unit 500 further includes a side part 518 connected to the connection part 516, and the side part 518 is arranged in parallel with the two leg parts 520. Specifically, the side part 518 is a portion extending along the Z axis as shown in FIG. 5B, while the connection part 410 only has a portion extending along the Y direction. Accordingly, when the first core unit 500 is coupled to the second core unit 310, since the magnetic flux can be transmitted to the second core unit 310 through the side part 518 of the first core unit 500 that extends along the Z direction, the connection part 516 of the first core unit 500 that extends along the Y direction has a smaller thickness T2. That is, the thickness T2 of the connection part 516 is smaller than the thickness T1 of the connection part 410.

In one embodiment, the PCB 210 as shown in FIG. 2A is a multilayer PCB. The transformer module includes a primary winding and a secondary winding wound around the magnetic core (e.g., leg parts 312 and 314 as shown in FIG. 3B). Specifically, the primary winding and the secondary winding are formed by traces on multiple layers of the PCB, and the multiple layers are stacked vertically to form a winding stack. FIG. 6 schematically shows a primary winding formed on one layer 600 of a PCB in accordance with an embodiment of the present disclosure. As shown in FIG. 6, the traces of the primary winding forms a spiral pattern on one layer 600 of the PCB. Specifically, the spiral pattern has a number of turns. For example, a winding W1 is wound around one of leg parts 620 with 2 turns, and a winding W2 is wound around the other of the leg parts 620 with 2 turns. Each of the windings W1 and W2 has a first turn 611 and a second turn 612. The first turn 611 has a width D1, the second turn 612 has a width D2, and the width D1 is smaller than the width D2.

FIG. 7 schematically shows a primary winding formed on one layer 700 of a PCB in accordance with another embodiment of the present disclosure. As shown in FIG. 7, a winding W3 is wound around one of leg parts 720, and a winding W4 is wound around the other of the leg parts 720. Each of the windings W3 and W4 has a first turn 711, a second turn 712, and a third turn 713. The first turn 711 has a width D3, the second turn 712 has a width D4, and the third turn 713 has a width D5. The width D3 is smaller than the width D4, and the width D4 is smaller than the width D5.

In some embodiments, the primary winding of the transformer (e.g., the winding NP as illustrated in FIG. 1) has a configuration as shown in FIG. 6 or FIG. 7. In the embodiments of FIGS. 6 and 7, the width of the winding increases from the inner turn to the outer turn in order to reduce the overall winding loss of the transformer. In some embodiments, the widths of the turns are predetermined so that each turn has a winding loss that is substantially the same.

As discussed above, the transformer module 240 is a planar transformer that includes a set of primary layers NP and a set of secondary layers. Specifically, the secondary layers further includes a set of first secondary layers NS1, and a set of second secondary layers NS2. In one embodiment, the primary winding and the secondary windings (NP, NS1, NS2) are formed on different layers of PCBs, and these layers of PCBs may be stacked vertically (e.g., along the Z direction) to form a winding stack in an order as shown in Table 1 below.

TABLE 1

| | |
|---|---|
| L1 | NS1 |
| L2 | NP |
| L3 | NS2 |
| L4 | NS2 |
| L5 | NP |
| L6 | NS1 |
| L7 | . . . |

As shown in Table 1, the first layer L1 is the winding NS1, the second layer L2 is the winding NP, the third layer L3 is the winding NS2, the fourth layer L4 is the winding NS2, the fifth layer L5 is the winding NP, the sixth layer L1 is the winding NS1, and so on. The primary layer NP is arranged between the first secondary layer NS1 and the second secondary layer NS2. In other words, each of the winding NP is sandwiched by a winding NS1 and a winding NS2.

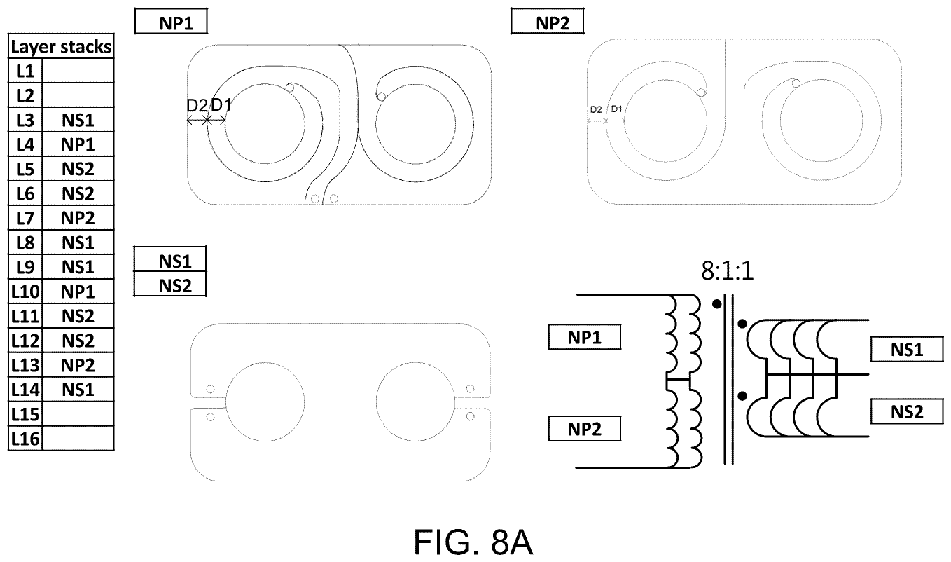

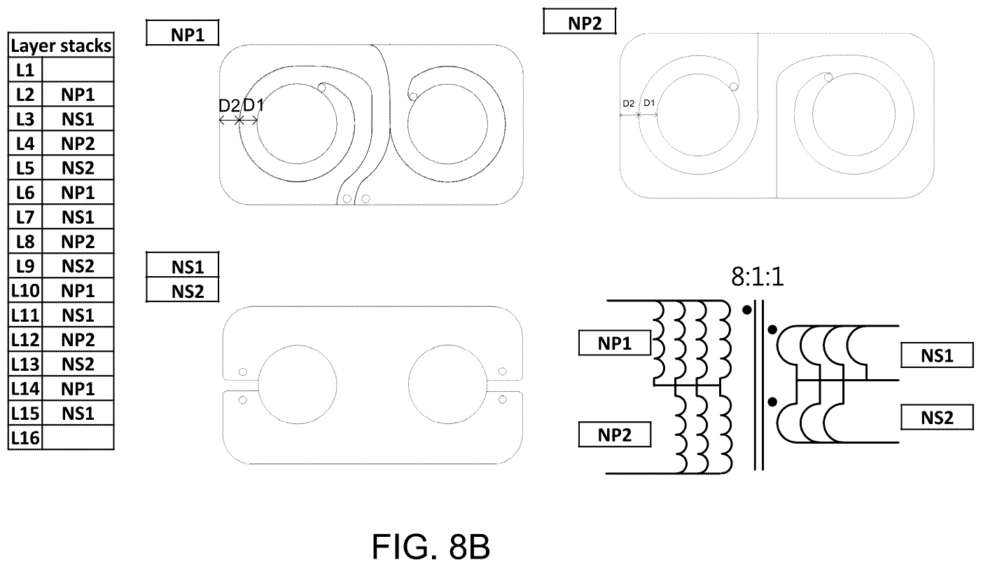

Specifically, FIG. 8A shows a schematic diagram of a winding stack formed on multilayer PCB with traces of the primary/secondary winding on each layer of the PCB. As shown in FIG. 8A, the winding stack includes a set of primary layers (e.g., NP1 and NP2), a set of first secondary layers (e.g., NS1), and a set of second secondary layers (e.g., NS2). For instance, the primary layers includes the PCB layers L4, L7, L10, and L13, the first secondary layers includes the PCB layers L3, L8, L9, and L14, and the second secondary layers includes the PCB layers L5, L6, L11, and L12.

In an alternative embodiment, the windings NP, NS1, NS2 are formed on different layers of PCBs, and these layers of PCBs may be stacked vertically (e.g., along the Z direction) in an order as shown in Table 2 below.

TABLE 2

| | |
|---|---|
| L1 | NP |
| L2 | NS1 |
| L3 | NP |
| L4 | NS2 |
| L5 | NP |
| L6 | NS1 |
| L7 | . . . |

As shown in Table 2, the first layer L1 is the winding NP, the second layer L2 is the winding NS1, the third layer L3 is the winding NP, the fourth layer L4 is the winding NS2, the fifth layer L5 is the winding NP, the sixth layer L1 is the winding NS1, and so on. In other words, each winding NP is followed by a winding NS1 or a winding NS2, and the number of the layers of the winding NP is larger than the number of the layers of the winding NS1 or NS2.

FIG. 8B shows a schematic diagram of a winding stack in accordance with another embodiment. As shown in FIG. 8B, the winding stack includes a set of primary layers (e.g., NP1 and NP2), a set of first secondary layers (e.g., NS1), and a set of second secondary layers (e.g., NS2). For instance, the primary layers includes the PCB layers L2, L4, L6, L8, L10, L12, and L14, the first secondary layers includes the PCB layers L3, L7, L11, and L15, and the second secondary layers includes the PCB layers L5, L9, and L13.

In some embodiments, when the layers of the windings NP, NS1, NS2 are stacked in the order as shown in Table 1 or 2, current distribution in each layer of the PCBs becomes even, and heat dissipation may be improved.

Therefore, the present invention provides a power module that has co-packaged switches and driver circuits. In some embodiments, the number of ICs arranged on the power module may be equal to or less than 11. In addition, due to the arrangement of the transformer module, the secondary switches, and the output capacitors, the power module may have reduced placement area. Moreover, due to the varying width of the primary winding and the order of the stacked PCB layers, the windings of the transformer may have even current distribution, improved heat dissipation, and improved efficiency.

It will be appreciated by persons skilled in the art that the present disclosure is not limited to what has been particularly shown and described herein above. Rather the scope of the present disclosure includes both combinations and sub-combinations of the various features described hereinabove as well as variations and modifications thereof which would occur to persons skilled in the art upon reading the foregoing description and which are not in the prior art.

What is claimed is:

1. A power module, comprising:
a printed circuit board (PCB) having a top surface and a bottom surface;
a transformer module disposed on the PCB, comprising:
a magnetic core having a first core unit arranged on the top surface of the PCB and a second core unit arranged on the bottom surface of the PCB;
a primary winding wound around the magnetic core; and
a secondary winding wound around the magnetic core;
wherein the primary winding is formed by traces on multiple layers of the PCB, the secondary winding is formed by traces on multiple layers of the PCB, and the multiple layers are stacked vertically to form a winding stack; and
a power converter circuit having a plurality of power switches, wherein a part of the power switches are disposed on the top surface of the PCB, and another part of the power switches are disposed on the bottom surface of the PCB.

2. The power module of claim 1, wherein the first core unit is an I-shaped core.

3. The power module of claim 1, wherein the first core unit is a U-shaped core having two leg parts and a connection part connected to the two leg parts.

4. The power module of claim 3, wherein the first core unit further comprising:
a side part connected to the connection part, wherein the side part is arranged in parallel with the two leg parts.

5. The power module of claim 1, wherein a transformer turn ratio of the transformer module is configured to provide a conversion ratio of the power converter circuit.

6. The power module of claim 1, wherein the traces of the primary winding forms a spiral pattern on one layer of the PCB, the spiral pattern has a number of turns, and wherein a width of the first turn of the spiral pattern is different from the width of the second turn of the spiral pattern.

7. The power module of claim 1, wherein the winding stack includes a set of primary layers, a set of first secondary layers, and a set of second secondary layers, wherein the primary layer is arranged between the first secondary layer and the second secondary layer.

8. The power module of claim 1, wherein the power converter circuit includes a primary side circuit and a secondary side circuit, wherein the primary side circuit comprises a plurality of primary side switches disposed on the top surface of the PCB.

9. The power module of claim 1, wherein the power converter circuit includes a primary side circuit and a secondary side circuit, and the secondary side circuit comprises a plurality of rectifiers disposed on the top surface of the PCB and the bottom surface of the PCB.

10. The power module of claim 9, wherein the transformer module is arranged between two rectifiers on the top surface of the PCB.

11. The power module of claim 9, wherein the secondary side circuit further comprises a plurality of output capacitors, and the output capacitors are arranged adjacent to the rectifiers.

12. The power module of claim 1, wherein the power converter circuit includes a primary side circuit and a secondary side circuit, and the primary side circuit includes a full-bridge circuit.

13. The power module of claim 1, wherein the power converter circuit includes a primary side circuit and a secondary side circuit, and the secondary side circuit includes a center-tapped rectifier circuit.

14. The power module of claim 1, wherein the power converter circuit and the transformer module forms an LLC converter.

15. The power module of claim 1, wherein the power converter circuit and the transformer module forms a non-isolated LLC converter.

16. The power module of claim 1, wherein a driver circuit and one of the power switches are integrated in an IC.

17. A planar transformer module, comprising:
a PCB having a top surface and a bottom surface;
a magnetic core having at least one leg part passing through multilayers of the PCB, a first unit arranged on the top surface of the PCB and a second unit arranged on the bottom surface of the PCB;
a winding stack formed by traces on the multiple layers of the PCB, wherein the winding stack includes a set of primary layers and a set of secondary layers, and the traces wound around the at least one leg part of the magnetic core; and
a power converter circuit includes a primary side circuit and a secondary side circuit, wherein the secondary side circuit comprises a plurality of rectifiers, wherein the magnetic core is arranged between two rectifiers on the top surface of the PCB, and the rectifiers are distributed evenly on the top surface and the bottom surface of the PCB.

18. The planar transformer module of claim 17, wherein the traces on the primary layer forms a spiral pattern having a number of turns, and wherein a width of the first turn of the spiral pattern is different from the width of the second turn of the spiral pattern.

19. The planar transformer module of claim 17, wherein the secondary layers includes a set of first secondary layers and a set of second secondary layers, wherein the primary layer is arranged between the first secondary layer and the second secondary layer.

20. The planar transformer module of claim 17, wherein the primary side circuit comprises a plurality of primary side switches disposed on the top surface of the PCB.

21. The planar transformer module of claim 17, wherein the secondary side circuit further comprises a plurality of output capacitors, and the rectifier is arranged between the output capacitors.

22. The planar transformer module of claim 17, wherein the power converter circuit includes a primary side circuit and a secondary side circuit, and the primary side circuit includes a full-bridge circuit, and the secondary side circuit includes a center-tapped rectifier circuit.
